(19) United States
(12) Patent Application Publication
(10) Pub. No.: US 2019/0221740 A1
(43) Pub. Date: Jul. 18, 2019

(54) Maskless surface energy modification with high spatial resolution

(71) Applicant: Universal Display Corporation, Ewing, NJ (US)

(72) Inventors: William E. QUINN, Whitehouse Station, NJ (US); Gregory MCGRAW, Yardley, PA (US)

(21) Appl. No.: 16/240,814

(22) Filed: Jan. 7, 2019

Related U.S. Application Data
(60) Provisional application No. 62/616,487, filed on Jan. 12, 2018.

(51) Int. Cl. H01L 51/00; H01L 51/56; H01L 51/52; B41J 2/135

(52) U.S. Cl. CPC H01L 51/0005; H01L 51/56; B41J 2/135; H01L 51/0094; H01L 51/5253

(57) ABSTRACT

Embodiments of the disclosed subject matter provide a method of modifying the surface energy of a substrate is provided. A first hydrophobic material may be directly printed, using a vapor ejected from a first nozzle, onto a hydrophilic substrate to surround at least a first area of the substrate, where the first material has a vapor pressure of at least 1 Pa at 300° C. A second material may be deposited, from a second nozzle, onto the first area of the substrate.

### CROSS-REFERENCE TO RELATED APPLICATIONS

This application claims priority to U.S. Patent Application Ser. No. 62/616,487, filed Jan. 12, 2018, the entire contents of which are incorporated herein by reference.

### FIELD

The present invention relates to modifying a surface energy of a substrate by directly printing a first hydrophobic material onto a hydrophilic substrate to surround at least a first area of the substrate, and depositing a second material onto the first area of the substrate to form devices.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

### SUMMARY

According to an embodiment, an organic light emitting diode/device (OLED) is also provided. The OLED can include an anode, a cathode, and an organic layer, disposed between the anode and the cathode. According to an embodiment, the organic light emitting device is incorporated into one or more device selected from a consumer product, an electronic component module, and/or a lighting panel.

According to an embodiment, a method of modifying the surface energy of a substrate is provided. A first hydrophobic material may be directly printed, using a vapor ejected from a first nozzle, onto a hydrophilic substrate to surround at least a first area of the substrate, where the first material has a vapor pressure of at least 1 Pa at 300° C. A second material may be deposited, from a second nozzle, onto the first area of the substrate. The ejected first hydrophobic material may form a perimeter around the deposited second material on the substrate. The first hydrophobic material may be a monolayer of organosilanes. The first hydrophobic material may be surfactants that physadsorb to the substrate, and/or fluoropolymers that change a surface energy of the substrate by 10% or more. The method may include processing performed before the second material is deposited, where the processing includes performing at least one of cleaning, blanket thin film deposition, and/or photolithography to form a device on the substrate. The deposited second material may be ink, and the deposited ink may include an electronically active material in print zones circumscribed by the first hydrophobic material. The ink may include at least one of organic material, semiconductor material, pigment, quantum dots, liquid crystal, and/or biological material. The method may include performing drying of at least the depositing the second material and subsequent processing. The method may include where the ejecting the first hydrophobic material is performed at an operating temperature of 80° C. to 150° C. The first hydrophobic material may be ejected in a plurality of passes to change a surface energy of the substrate by 15% or greater. The ejected first hydrophobic material may form a pattern that may be a perimeter pattern or an annular pattern.

### BRIEF DESCRIPTION OF THE DRAWINGS

FIG. 1 shows an organic light emitting device.

FIG. 2 shows an inverted organic light emitting device that does not have a separate electron transport layer.

FIGS. 3A-3B show a depositor with delivery, exhaust, and confinement flows used for organic vapor jet printing according to embodiments of the disclosed subject matter.

FIG. 4 shows a diagram of a tool for depositing surface energy modification agents by vapor jet printing according to an embodiment of the disclosed subject matter.

FIG. 5 shows an example of a structure that can be made by inkjet printing following surface energy modification vapor jet printing (SEMVJP) according to an embodiment of the disclosed subject matter.

FIG. 6 shows an example method of using SEMVJP in a fabrication process having a wet printing step according to an embodiment of the disclosed subject matter.

FIG. 7 shows an SEMVJP depositor optimized to create a sharp transition between hydrophobic and hydrophilic regions according to an embodiment of the disclosed subject matter.

FIG. 8 shows a contour plot of the flux of surface energy modification agent adsorbing onto a substrate processed by SEMVJP according to an embodiment of the disclosed subject matter.

FIGS. 9A-9B show an average dosage of surface energy modification agent along a width of a hydrophobic fence structure deposited by SEMVJP according to embodiments of the disclosed subject matter.

FIG. 10 shows an example of a depositor to deposit a hydrophobic fence structure that generates sharp transitions between hydrophobic and hydrophilic regions on both sides of the structure according to an embodiment of the disclosed subject matter.

FIGS. 11A-11B show the average dosage of surface energy modification agent along the width of a hydrophobic fence structure deposited by SEMVJP using the depositor in FIG. 10 according to an embodiment of the disclosed subject matter.

FIGS. 12A-12B show examples of an annular depositor designed to deposit a hydrophobic fence structure that contains discrete or curving segments according to embodiments of the disclosed subject matter.

FIGS. 13A-13B show the average dosage of surface energy modification agent along the width of a hydrophobic fence structure deposited by SEMVJP using the depositor in FIGS. 12A-12B according to embodiments of the disclosed subject matter.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

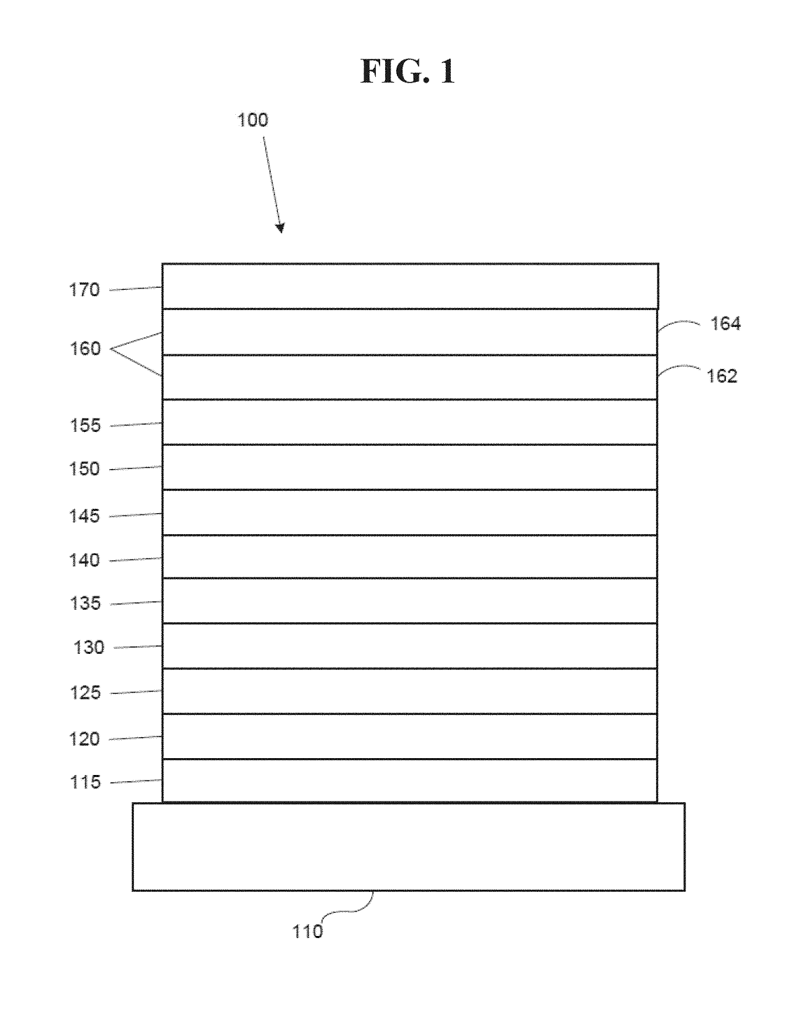

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

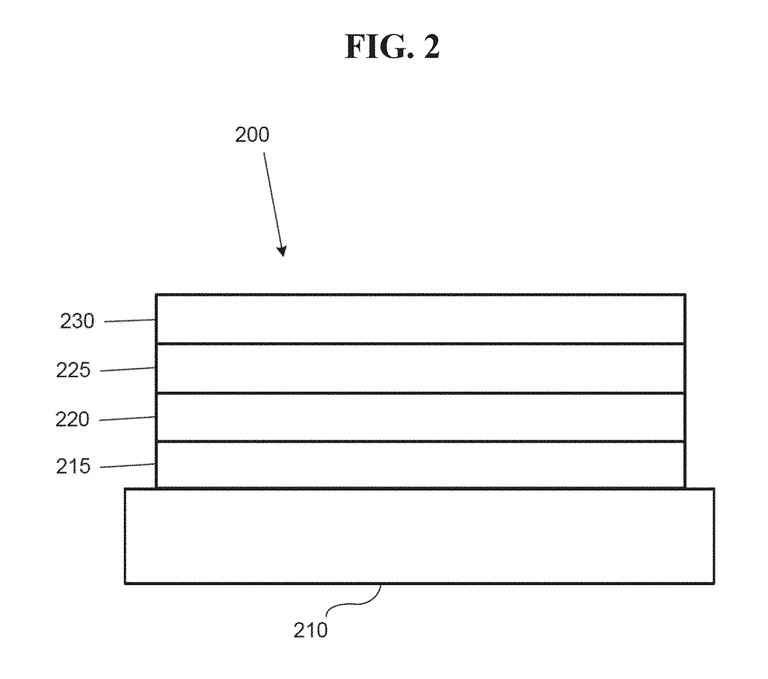

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, computer monitors, medical monitors, televisions, billboards, lights for interior or exterior illumination and/or signaling, heads-up displays, fully or partially transparent displays, flexible displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

### Formation of Devices

Thin films of hydrophobic or hydrophilic materials may be deposited on a substrate to affect the wetting behavior of liquids deposited on them. They may be applied over a large area, as is standard procedure to promote photoresist adhesion in photolithography.

Alternately, surface energy modification agents may be applied selectively to microscopic regions to generate patterns on a substrate. This may be done using a stamp to transfer hydrophobic material, as described, for example, by Drelich et al., “Wetting Characteristics of Liquid Drops at Heterogeneous Surfaces,” Colloids and Surfaces, A: Physiochemical and Engineering Aspects 93, pp. 1-13 (1994). Other methods include using photo-initiated surface modification agents, as described, for example. Surface energy modification may be performed by dry processing as well. This may be achieved by vacuum deposition through shadow mask as described by, for example, Gau et al., “Liquid Morphologies on Structured Surfaces: From Microchannels to Microchips,” Science, 1 Jan. 1999, 283 5398, pp. 46-49. A hydrophilic material, such as MgF₂, may be deposited on hydrophobic substrates such as silicone rubber. P. Lenz, “Wetting Phenomena on Structured Surfaces,” Adv. Materials, 11, No. 18, pp. 1531-1532 (1999) provides a review of surface energy patterning technologies.

Although surface energy modification may be performed by wet processing, it is ill-suited to inkjet printing. Agents that make a hydrophilic surface hydrophobic have very low surface tension and tend to disperse on a substrate instead of remaining in well-defined droplets. The disclosed subject matter may print patterns on demand since no pre-made stamp or mask is required. The disclosed subject matter also provides a non-contact method by which a hydrophobic coating can be applied to a hydrophilic substrate. The process may be performed at atmosphere, and even in room air if desirable.

Patterned surface energy modification may have many applications in the field of printed electronics. It may be used in conjunction with inkjet printing to define the regions wetted by inks containing electronically active materials and prevent spillage into neighboring structures. Sirringhaus et al., “High-resolution Inkjet Printing of All-Polyment Transistor Circuits.” Science, vol. 290, pp. 2123-2126 (2000), describes high resolution inkjet printing of the source and drain electrodes of organic thin film transistors by defining hydrophilic wells at printing targets on their substrate. The wells were made through a combination of photolithography to protect hydrophobic areas and an O₂ plasma surface activation to increase the surface energy of exposed areas. Ink beaded remains beaded over hydrophilic regions as it dries. This improves the uniformity of the active regions and prevents ink from spreading onto other electrodes. A similar approach may be used to define the active areas of solution processed OLEDs. Patterned surface energy modification is also widely used in biotechnology, both to fabricate microassays and to control the flow of reagents and analytes in finished microfluidic systems. See, e.g., Gau et al., “Liquid Morphologies on Structured Surfaces: From Microchannels to Microchips,” Science, 1 Jan. 1999, 283 5398, pp. 46-49.

The OVJP technology developed by Universal Display Corp. related to delivery-exhaust-confinement or DEC OVJP is described in US 2015/0376787. This can be adapted to print a thin film of HMDS (hexamethyldisilazane) or other high vapor pressure surface modification agent instead of evaporated OLED materials. US 2015/0376787 also references US 2015/380648, which discloses how to start and stop printed lines by lowering and raising the print head relative to the substrate. It enables discontinuous segments of lines to be printed with minimal run-out at the termination of the segments. Application U.S. Ser. No. 15/475,408 (US 2017/0294615) describes a depositor design capable of generating sharp transitions between printed and non-printed regions. This is a desirable feature for surface modification.

OVJP can be transformed from an OLED deposition tool to a surface energy modification tool by changing the type of source material it deposits and adapting the tool to the optimal process conditions for the new materials. The surface energy modification agent will act on the region underneath its depositor and not and the surrounding area. The disclosed technique is referred to as Surface Energy Modification Vapor Jet Printing (SEMVJP).

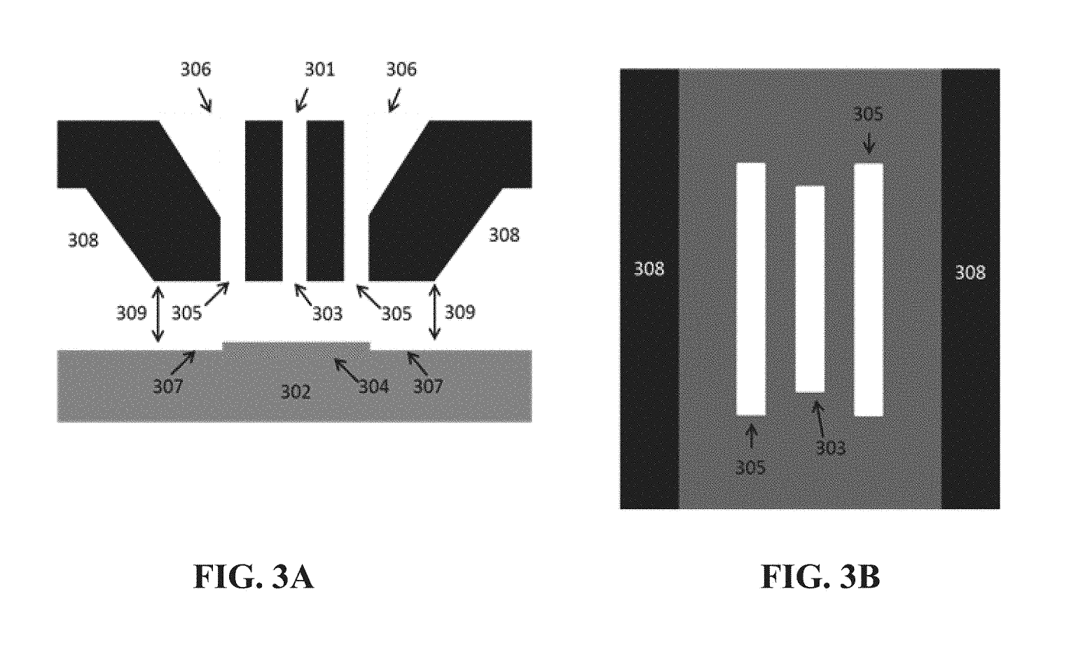

OVJP currently operates by depositing a thin film of organic semiconductor materials on well-defined regions of a substrate with a resolution of 100 μm or less. FIGS. 3A-3B show a depositor with delivery, exhaust, and confinement flows used for organic vapor jet printing according to embodiments of the disclosed subject matter. FIG. 3A shows a depositor in cross section, and FIG. 3B shows its lower surface from the perspective of the substrate. The material to be deposited travels via a delivery channel 301 entrained in a flow of inert delivery gas that forms a jet onto a substrate 302 as it exits delivery aperture 303. A portion of the material in the delivery jet is adsorbed onto the substrate 302 underneath a depositor 304, and the remainder is drawn into an exhaust aperture 305 along with the delivery gas. An exhaust channel 306 connected to the exhaust aperture 305 transports gas from the printing zone to a low pressure sink external to it. The exhausts draw a larger molar flow of gas from the printing zone than is ejected by the delivery jet, creating a net inflow of gas from the surrounding environment. This inward convection forms a confinement flow that moves inward to the deposition zone to resist the spread of the deposition material beyond the intended printing zone. Regions 307 of the substrate 302 that are to the sides of the depositors are therefore not covered by the deposited material. The confinement flow is distributed evenly along the length of the depositor by transverse channels 308, and moves into the deposition zone through the gap 309 between the underside of the print head and the substrate. Alternate configurations of delivery, exhaust, and confinement flow are possible, however at least some of these techniques rely on the use flows of delivery and confinement gas driven by micronozzle arrays to convectively control the deposition of vapor.

Use of an OVJP like process to deposit material in monolayers created by self-limiting chemical reactions is described in UDC-1300 (U.S. 62/651,780). This was done in the context of building thin films by depositing successive monolayers in a manner similar to atomic layer deposition. The subject matter disclosed herein differs from the previous one because it discloses depositing a single monolayer of chemically non-reactive material.

Hexamethyldisilazane (HMDS) vapor is commonly used as a treatment to reduce the surface energy of Si and glass substrates. It chemically reacts with surface oxide (R—OH) to create a surface covered in a monolayer of siloxyl groups (R—O—Si(CH₃)₃). Thickness control of the layer is straightforward, since adsorption self-limits once a monolayer is deposited. HMDS is a liquid at room temperature and it is relatively volatile, with a boiling point of 127° C. A related compound, trichloro(octadecyl)silane (OTS) is also a liquid at room conditions and has a boiling point of 223° C. Depositing either material by SEMVJP would typically use a heated manifold and print head.

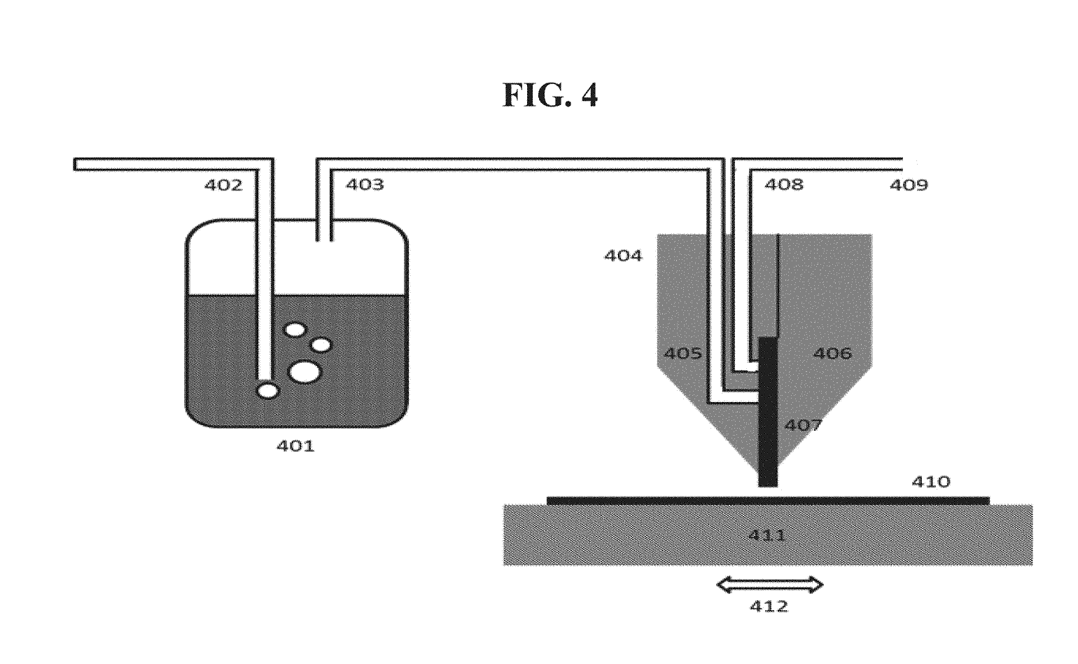

In the embodiments discussed below in connection with FIGS. 4-13B, a surface energy of a substrate may be modified. A first hydrophobic material may be directly printed, using a vapor ejected from a first nozzle, onto a hydrophilic substrate to surround at least a first area of the substrate. The first material may have a vapor pressure of at least 1 Pa at 300° C. A second material may be deposited, from a second nozzle, onto the first area of the substrate. The ejected first hydrophobic material may form a perimeter around the deposited second material on the substrate.

The first hydrophobic material may be a monolayer of organosilanes. The first hydrophobic material may be surfactants that physadsorb to the substrate, and/or fluoropolymers that change a surface energy of the substrate by 10% or more. The deposited second material may be ink, and the deposited ink may include an electronically active material in print zones circumscribed by the first hydrophobic material. The ink may include at least one of organic material, semiconductor material, pigment, quantum dots, liquid crystal, and/or biological material.

In some embodiments, processing may be performed before the second material is deposited. Such processing may include performing at least one of cleaning, blanket thin film deposition, and/or photolithography to form a device on the substrate. In some embodiments, drying of at least the deposited second material may be performed.

The ejecting of the first hydrophobic material may be performed at an operating temperature of 80° C. to 150° C. The first hydrophobic material may be ejected in a plurality of passes to change a surface energy of the substrate by 15% or greater. The ejected first hydrophobic material may form a pattern that may be a perimeter pattern or an annular pattern.

FIG. 4 shows a tool for depositing surface energy modification agents by vapor jet printing according to an embodiment of the disclosed subject matter. OVJP normally uses sublimation oven containing solid source materials. However, it can be readily adapted for use with a bubbler 401 for SEMVJP. Carrier gas may be fed into the bubbler 401 via line 402 at constant mass flow rate, and may leave the bubbler 401 through a heated runline 403 to a print head 404. The runline 403 enters the heated print head 404. The print head 404 may include a clamp with two sides 405, 406 and a die including a micronozzle array 407 within the clamp. Vapor from the runline 403 may pass through the clamp and into the die including a micronozzle array 407. Exhaust gasses exit the die through an exhaust line 408 that also passes through the clamp and outside 409 to a low pressure sink. The substrate 410 sits on a holder 411 below the print head 404. The substrate holder 411 may move in directions 412 relative to the print head 404. The tool may be operated in an inert environment at either atmospheric or reduced pressure.

A SEMVJP process that lowers the surface energy of desired regions using a monolayer of chemisorbed organosilanes is discussed below as the preferred embodiment. Other possible materials exist. It is desirable for candidate materials to have a relatively significant vapor pressure (>1 Pa) at or below 300° C. Low molecular weight surfactants that physadsorb to the substrate may also be used. Likewise, thin films of low molecular weight fluoropolymers or other bulk materials that have low surface energy may be deposited.

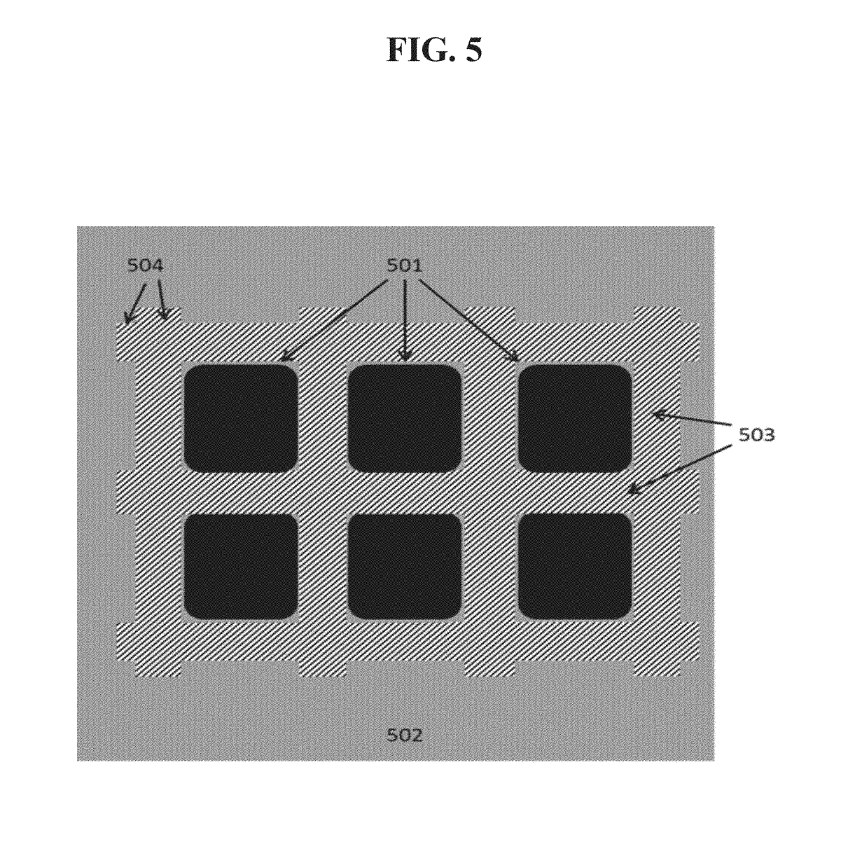

A tool that dispenses material that lowers the surface energy of a substrate may be useful in the fabrication of printed electronics. FIG. 5 shows an example of a structure that can be made by inkjet printing following surface energy modification vapor jet printing (SEMVJP) according to an embodiment of the disclosed subject matter. An array of six drops 501 of ink containing a desired material may be printed on a substrate 502. The substrate 502 may be hydrophilic. A grid of hydrophobic traces 503 may be drawn around the perimeter of the desired drop locations with the SEMVJP prior to wet printing. An OVJP print head (e.g., as shown in FIG. 3A) may print lines as opposed to dots. If a similar design is used in SEMVJP, it may also print in lines. Horizontal and vertical grid members may overlap each other at corners 504. Run-out distance at the ends of printed lines may be minimized by using fly height control to begin and end deposition at specific points on the substrate as described in US 2015380648 A1. Hydrophobic fences formed by monolayers may act as replacements for much thicker bank structures defined by photolithography that are frequently used in conjunction with inkjet printing.

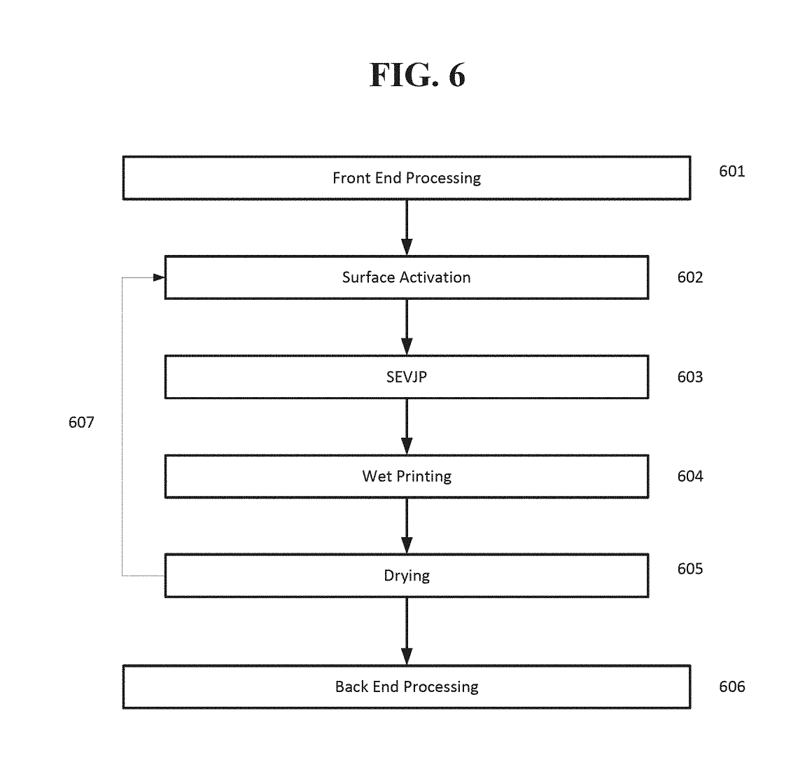

FIG. 6 shows an example method of using SEMVJP in a fabrication process having a wet printing step according to an embodiment of the disclosed subject matter. In some embodiments, the method shown in FIG. 6 may be used to form the structure shown in FIG. 5. The method may begin with front end processing 601, which may include cleaning, blanket thin film deposition and photolithography needed to make a device. Operations 602-605 shown in FIG. 6 may be part of the front end processing 601. The substrate (e.g., substrate 410 shown in FIG. 4) may receive a surface treatment 602 to increase its surface energy. The desired printing zones may be circumscribed with hydrophobic regions defined by exposure to the SEMVJP depositor 603. Ink containing electronically active material may deposited in the printed zones using inkjet or other wet technique 604. SEMVJP may be combined in a single tool with inkjet or other processes. The printing process and/or front end processing may be followed by a drying step 605. The front end processing 601, which may include operations 602-605, may be followed by the back end processing 606 to complete the device.

The ink in the described process may contain a wide range of materials depending on the function of the device being fabricated. It may contain organic or other semiconductor material for wet processed thin film transistors. Alternately, the ink may include electroluminescent materials for use in OLEDs or QLEDs (quantum dot light emitting device). It may contain optical elements like pigments, quantum dots, or liquid crystals. It may contain biological material like nucleic acids or proteins if it is part of a biochemical assay. The preceding examples are by no means exhaustive, and other materials may be included.

When printing HIVIDS by SEMVJP, surface modifications may be carried out in stages, which may enable the fabrication of denser and more complex structures than would otherwise be possible. Once a layer of material is deposited by inkjet printing and is dried, the surface energy configuration to facilitate its deposition may be removed by a plasma treatment. Another surface energy configuration may then be patterned by SEMVJP and used for a subsequent deposition by inkjet. This cycle 607 of performing operations 602-605 may be repeated for multiple times within the process flow if necessary.

Surface energy modification may increase the accuracy of wet printed features, since spatially controlled wetting can prevent splatter during the initial deposition or thickness non-uniformity as a printed film dries. This may increase a printing resolution. To be effective in this role, SEMVJP may generate a sharp transition between hydrophobic and hydrophilic regions on at least one side of the deposition profile. The transition may be achieved by a sharp cutoff of vapor flux onto the substrate between regions intended to be hydrophobic and regions intended to be hydrophilic.

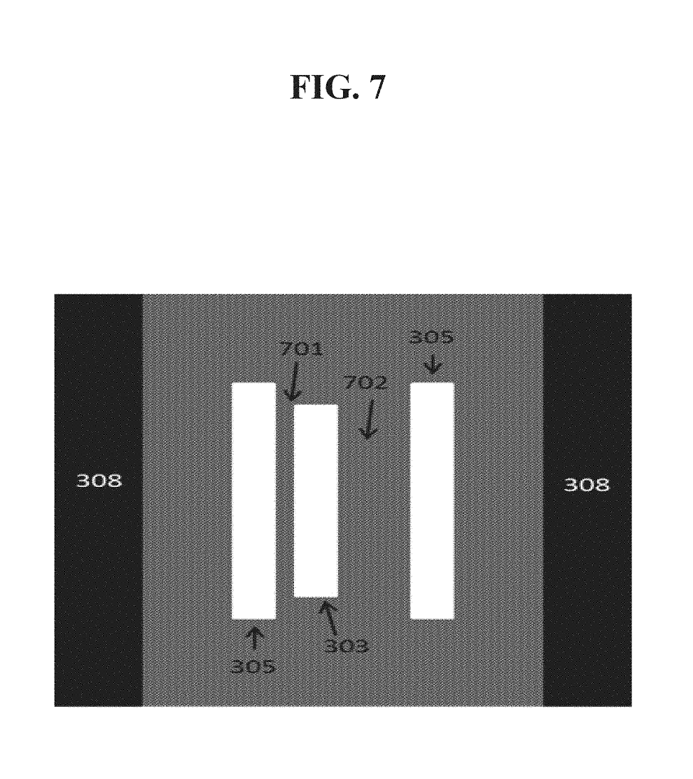

A sharp cutoff may be achieved by placing the print head close to the substrate. This can be done more readily with SEMVJP than OVJP, since its operating temperatures are in the range of 80-150° C., significantly less than OVJP. Fly heights in the range of 10-25 μm may be desirable. FIG. 7 shows an SEMVJP depositor optimized to create a sharp transition between hydrophobic and hydrophilic regions according to an embodiment of the disclosed subject matter. In particular, FIG. 7 shows an example of a depositor adapted for SEMVJP. In many arrangements it may be desirable for the width of a DE spacer 701 over the region of transition between hydrophobic and hydrophilic to be relatively narrow. The narrow DE spacer 701 may be a spacer between the delivery aperture 303 and the exhaust aperture 305. The wide DE spacer 702 on the other side of the delivery aperture 303 may be wider that narrow DE spacer 701, depending on the desired width of the hydrophobic fence. FIG. 7 also shows delivery aperture 303, exhaust aperture 305, and transverse channels 308, which are described above in connection with FIGS. 3A-3B.

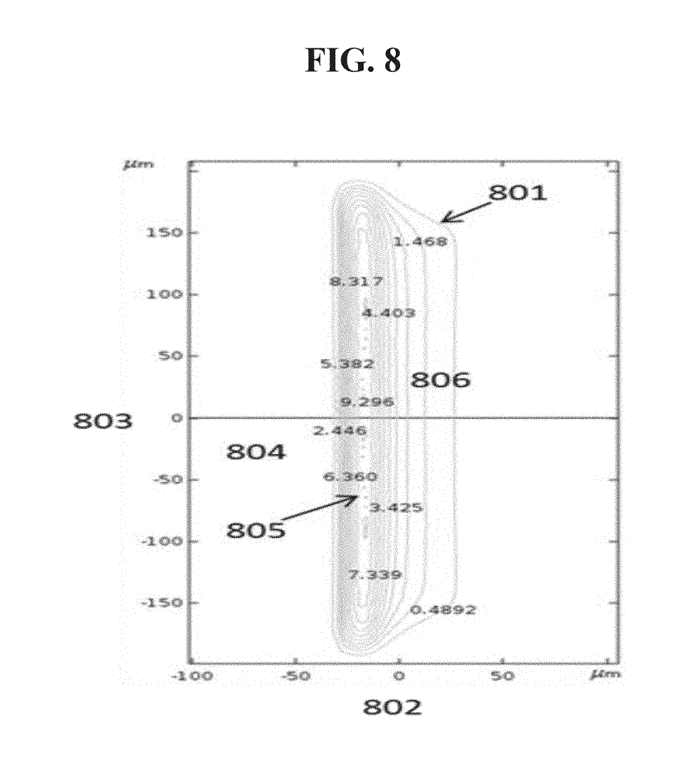

FIG. 8 shows a contour plot of the flux of surface energy modification agent adsorbing onto a substrate processed by SEMVJP according to an embodiment of the disclosed subject matter. The flux of organic vapor onto the substrate from this depositor is plotted as shown in FIG. 8. Normalized contours 801 of molar flux may be in arbitrary units. The horizontal 802 and vertical 803 axes show distance in microns perpendicular and parallel to the long axis of the depositor, respectively. Flux may rise from near zero 804 on the left hand side of the adsorption zone to a peak spatial flux 805. This may correspond to the side with the narrow DE spacer (e.g., narrow DE spacer 701 shown in FIG. 7). On the right hand side of the line of peak spatial flux is a more gradually receding flux profile 806, which may be due to the wide DE spacer.

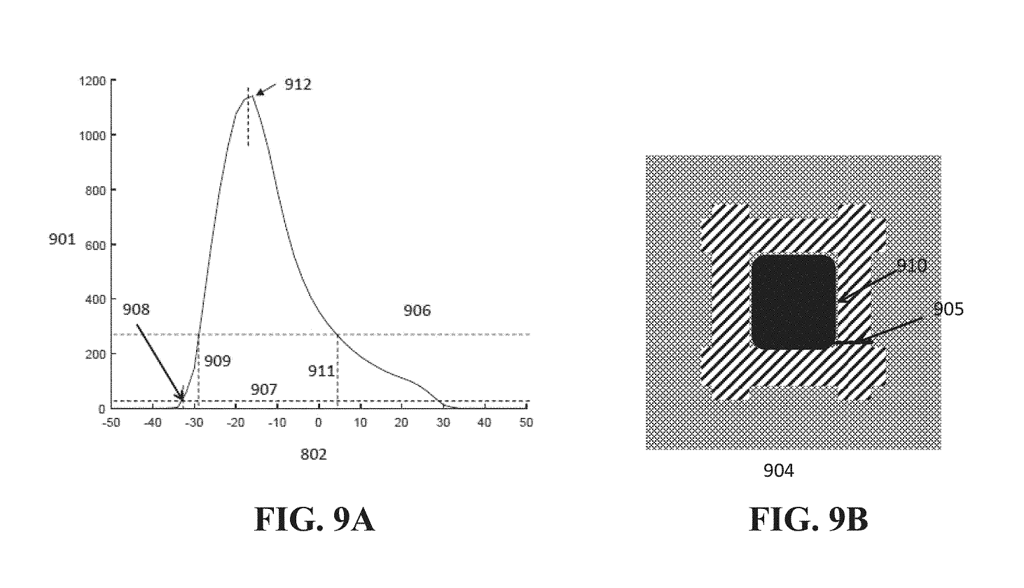

FIGS. 9A-9B show an average dosage of surface energy modification agent along a width of a hydrophobic fence structure deposited by SEMVJP according to embodiments of the disclosed subject matter. FIG. 9A shows the flux integrated in the vertical direction (from FIG. 8). This may account for the motion of the depositor with respect to the substrate parallel to the long axis of its apertures. The vertical axis 901 may have the integrated flux in arbitrary units, may be indicative of the net dosage of vapor along a cross section of hydrophobic fence. As shown in FIG. 9B, a dot 902 may be printed with inkjet and surrounded with a hydrophobic fence 903. The cross section along which dosage of the surface modification agent is plotted is shows with a dashed line 905. The flux dosage to generate a monolayer of surface modifier may be plotted as a horizontal line 906, as shown in FIG. 9A. Another horizontal line may plotted below it, as shown in FIG. 9A, which may indicate an adsorption of 1/10 of a monolayer 907. The deposition profile may be optimized so that there is a rapid spatial transition from a region that receives a minimal flux dosage to one large enough to generate a monolayer.

Regions to the left of the leftmost vertical line 908 shown in FIG. 9A may receive 1/10 of a monolayer or less. Regions to the right of the next line inside of it at 909, shown in FIG. 9A, may receive a full monolayer. The transition between these regions may indicate the transition between a wetting and non-wetting zone. In the present case, this transition may be 4 microns, implying that the position of the edge of a printed drop 910 may be controlled to within 4 microns. Regions between the latter line and the next line on the right 911 (shown in FIG. 9A) may receive a full monolayer of surface treatment. The width between these lines defines the width of the fence, for example, 33 μm in this case.

The peak dosage 912 of surface modifier deposited within the fence may be considerably greater than required to achieve a monolayer and the dose across the fence may be relatively non-uniform. This may not adversely affect the quality of surface modification, since adsorption of organosilanes and other surface modification agents self-limits after a monolayer is deposited. A higher dosage may not change the surface properties. If physisorbed treatment such as a low molecular weight fluoropolymer is used instead of an organosilane, excess material around the dosage peak is still unlikely to create issues. The deposited layer is very thin relative to other layers in the structure, and the goal is hydrophobicity rather than uniform thickness.

If it is desired to print neighboring features, the fence structure may be printed in two passes, such that an edge featuring a sharp transition between hydrophobic and hydrophilic regions abuts each printed droplet. Alternately, a depositor with a split delivery aperture as described in U.S. patent application Ser. No. 15/475,408, now U.S. Publn. No. 2017/0294615, may be used to generate a dosage profile with a sharp transition between hydrophilic and hydrophobic on each side.

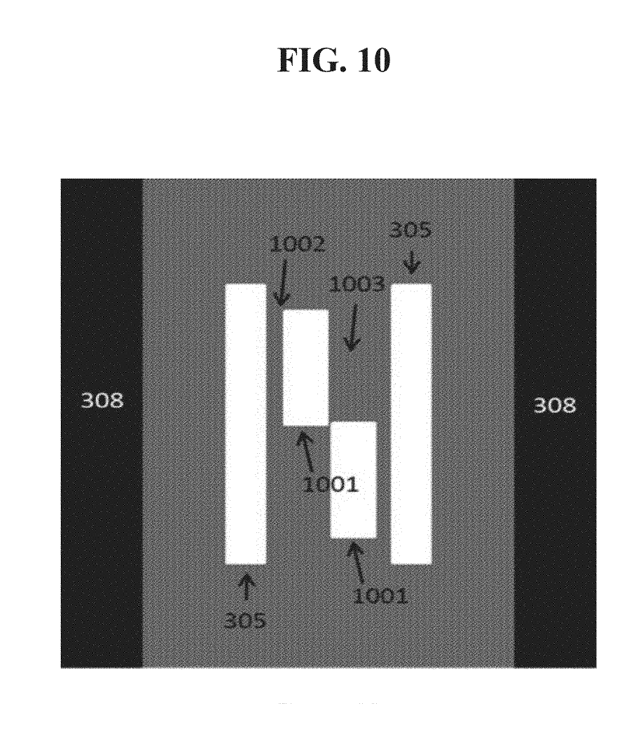

An example split delivery aperture depositor is shown in FIG. 10. The delivery aperture 1001 may be separated into two segments that are offset from each other. On one side of each segment of the delivery aperture 1001 is a first 1002 spacer (i.e., a DE narrow spacer) between the delivery and exhaust apertures and on the other side is a second 1003 spacer (i.e., a DE wide spacer). The first spacer 1002 may be narrower than the second spacer 1003, and the second spacer 1003 may be wider than the first spacer 1002. The positions of the spacers 1002, 1003 may reverse themselves between the top and bottom delivery aperture. FIG. 10 also shows exhaust aperture 305, and transverse channels 308, which are described above in connection with FIGS. 3A-3B.

Different depositor designs may be used depending on the desired application. If a deposited profile is used to define the extents of a droplet, the delivery and exhaust apertures (e.g., delivery aperture 1001 and exhaust aperture 305 shown in FIG. 10) of the depositor may be positioned closely together along an edge, and the depositor-to-substrate fly height may be small, such as 10 μm to 150 μm. As with OVJP, SEMVJP depositors may be formed from micro-fabricated micronozzle arrays and deployed in parallel on a common print head.

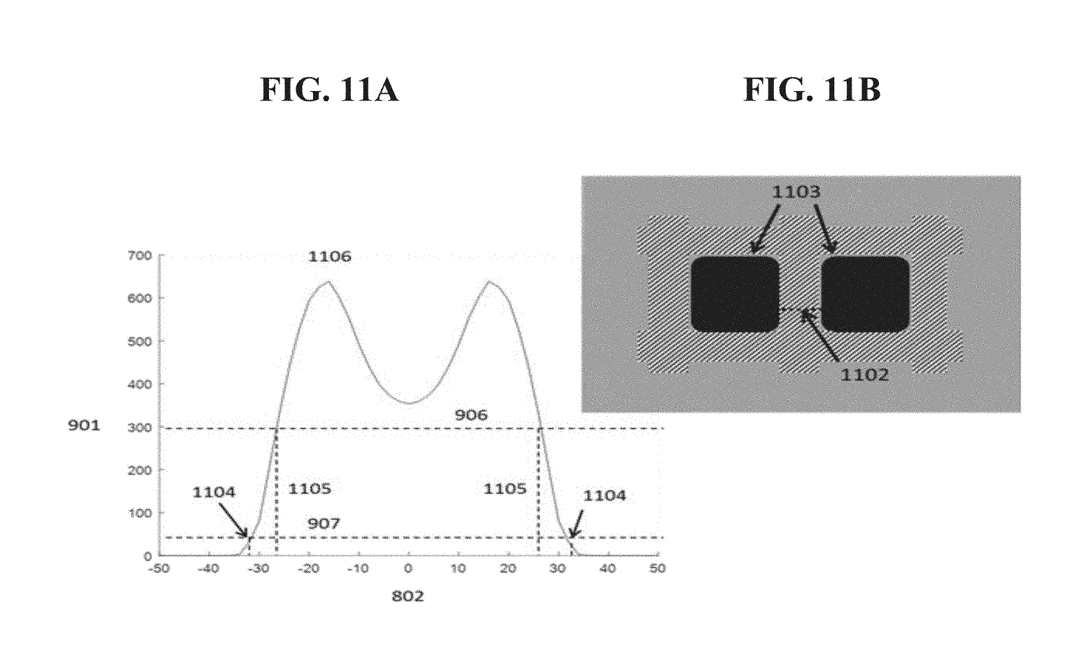

The dosage profile generated by the depositor in FIG. 10 is shown in FIG. 11A. The profile gives the dosage across the hydrophobic fence shown in FIG. 11B by the dotted line 1102. The fence separates two droplets 1103 deposited by inkjet printing. The rise of the dosage profile from the lower horizontal line indicating 10% coverage of surface modification agent to the upper horizontal line indicating a full monolayer of coverage may be approximately 4 μm. This may be the case for both sides of the profile. The distance between the vertical 10% line 1104 and the nearest vertical 100% line 1105 may indicate the tolerance with which hydrophobic fences may be printed. The width of the hydrophobic fence may be defined by the distance between the two vertical 100% lines 1105, which may be 54 μm as shown in FIG. 11A. Excess deposition at the peaks 1106 of the dosage profile may not adversely affect film quality.

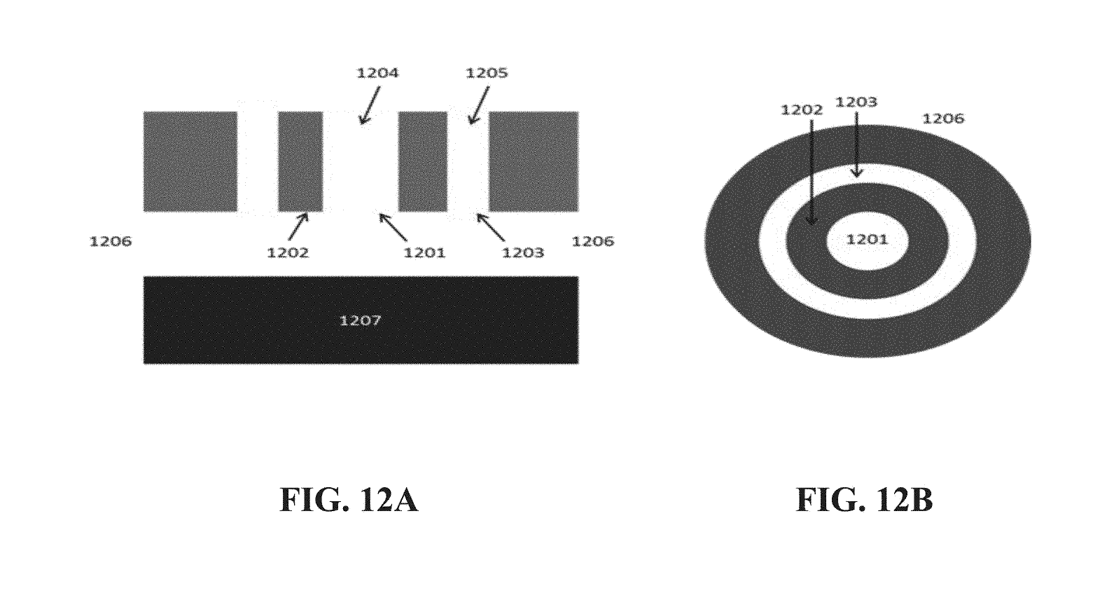

Hydrophobic fences may be used in configurations other than grids of lines. An annular depositor may provide more flexibility in patterning curved or discrete elements than the depositors with linear apertures discussed previously. An example of such a depositor is shown in FIGS. 12A-12B, where the depositor is shown in cross section, and where the lower surface of the depositor is shown from the perspective of the substrate (e.g., substrate 1207). The depositor may be cylindrically symmetric. The delivery aperture 1201 may be positioned at the center, and may be surrounded by a circular DE spacer 1202. The exhaust aperture 1203 may include an annulus around the DE spacer 1202. The delivery channel 1204 may be connected to the delivery aperture 1201, and may be coaxial to the surrounding exhaust channel 1205 that connects to the exhaust aperture 1203. As with the linear depositors, the annular depositor may eject a jet of surface modification agent from the delivery aperture, and may withdraw excess material through the exhaust aperture. Molar flow through the exhaust aperture may be greater than through the delivery aperture, so that confinement gas is drawn inward from the far field 1206 to resist the spread of surface modification agent. Patterns may be drawn by moving the substrate 1207 relative to the depositor. Deposition may be started by bringing the substrate 1207 into proximity with the depositor, and may be stopped by increasing the distance between the substrate and the depositor. Annular depositors, as well as other possible configurations of depositors, may be arranged in micronozzle arrays in a manner similar to depositors with linear apertures.

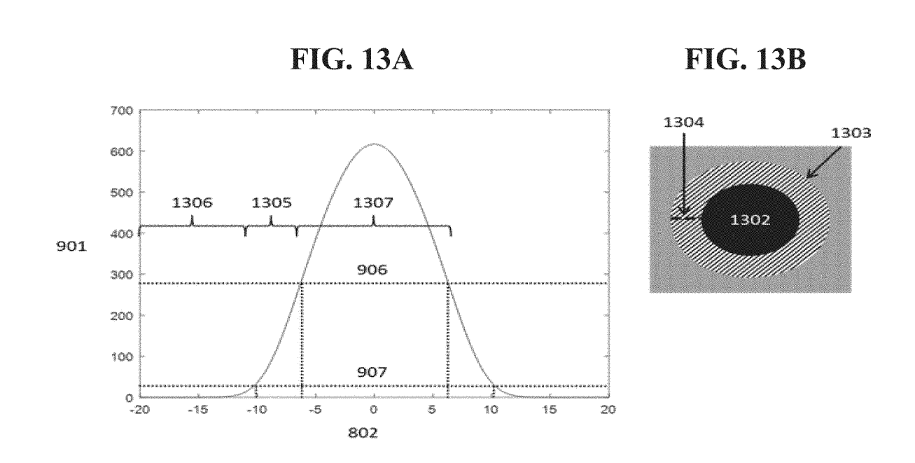

The dosage profile generated by the depositor in FIGS. 12A-12B is shown in FIG. 13A. An example of a hydrophobic fence structure having this type of depositor is shown in FIG. 13B. A round droplet deposited by inkjet 1302 may be surrounded by a circular fence 1303. The profile may give the dosage of surface modification agent across the hydrophobic fence along the cross section indicated the dotted line 1304. In some embodiments, the fence may be deposited in a continuous motion to create a stripe of modified surface. Alternatively, in some embodiments, the fence may be deposited in a curvilinear motion to modify the surface. As shown in FIG. 13A, the rise of the dosage profile from the lower horizontal line 907 indicating 10% coverage of surface modification agent to the upper horizontal line 906 indicating a full monolayer of coverage may be approximately 4 μm. This zone 1305 may be a border between hydrophilic regions beyond the fence trace 1306 and the hydrophobic regions of the fence trace 1307. The width of the border may provide an approximate indication of the placement accuracy of a drop within the fence. The width of the fence trace 1307 may be 12 μm, defined by the distance between the intersections between the dosage profile and the upper horizontal line 906.

As discussed above, SEMVJP may be used to deposit material that reduces substrate surface energy. It may alternately be used to dispense treatments that increase surface energy. Localized delivery and confinement allows a substrate to be selectively exposed to agents such as O₂, NO₂, or H₂O₂ vapor where needed in an otherwise inert environment. In addition to surface modification, oxidizing vapors may also be used to etch or ash blanket coat thin films, which may permit mask-free surface micromachining. Oxidizing vapors may be generated by chemical reaction in a source cell as opposed to simple evaporation. Oxidizers that are gaseous at room temperature may not use additional heating of the runline and depositor, but the temperature and ambient may be controlled to promote desired reaction kinetics.

### EXPERIMENTAL

The performance of the depositor described above in connection with FIGS. 3-13B was modeled using COMSOL Multiphysics 5.3. Fluid flow was modeled using the 3D laminar flow module. Heat flow, gas mixing, and transport of the surface modification agent were modeled using heat and mass transport modules. Transport coefficients were calculated from kinetic theory (see, e.g., Deen et al., Transport Phenomena, pp. 14-20) using HMDS as a representative surface modification agent.

A single delivery aperture depositor with a 10 by 380 μm delivery aperture surrounded by two 15 by 450 μm exhaust apertures on each side was modeled. The narrower spacer between the delivery and exhaust apertures was 5 μm wide and the wider spacer was 38 μm wide. The separation between the substrate and print head was 10 μm. A delivery flow of 1 sccm He was assumed, along with an exhaust flow of 10 sccm. The depositor was heated to 80° C. and the surrounding ambient was 20° C. The ambient was assumed to be Ar at 760 Torr. A depositor with split delivery apertures was modeled by substituting two 10 by 190 μm delivery apertures for the single aperture configuration above, with the positions of the wide and narrow spacers reversed for each of the two delivery apertures. Model conditions are otherwise unchanged.

The annular depositor was modeled using 2D axially symmetric versions of the previously described modules. The depositor had a delivery aperture diameter of 10 μm, a DE spacer width of 5 μm, an exhaust aperture width of 5 μm, and a 10 μm separation between the depositor and substrate. Delivery flow is 0.25 sccm He and the exhaust flow is 2.5 sccm. Other parameters are unchanged.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

We claim:

1. A method of modifying the surface energy of a substrate, the method comprising:
directly printing, using a vapor ejected from a first nozzle, a first hydrophobic material onto a hydrophilic substrate to surround at least a first area of the substrate, wherein the first material has a vapor pressure of at least 1 Pa at 300° C.; and
depositing, from a second nozzle, a second material onto the first area of the substrate.

2. The method of claim 1, wherein the ejected first hydrophobic material forms a perimeter around the deposited second material on the substrate.

3. The method of claim 1, wherein the first hydrophobic material is a monolayer of organosilanes.

4. The method of claim 1, wherein the first hydrophobic material is selected from the group consisting of: surfactants that physadsorb to the substrate, and fluoropolymers that change a surface energy of the substrate by 10% or more.

5. The method of claim 1, further comprising processing performed before the second material is deposited, the processing comprising:
performing at least one from the group consisting of: cleaning, blanket thin film deposition, and photolithography to form a device on the substrate.

6. The method of claim 1, wherein the deposited second material is ink.

7. The method of claim 6, wherein the deposited ink includes an electronically active material in print zones circumscribed by the first hydrophobic material.

8. The method of claim 6, wherein the ink comprises at least one from the group consisting of: organic material, semiconductor material, pigment, quantum dots, liquid crystal, and biological material.

9. The method of claim 1, further comprising:
performing drying of at least the depositing the second material and subsequent processing.

10. The method of claim 1, wherein the ejecting the first hydrophobic material performed at an operating temperature of 80° C. to 150° C.

11. The method of claim 1, wherein the first hydrophobic material is ejected in a plurality of passes to change a surface energy of the substrate by 15% or greater.

12. The method of claim 1, wherein the ejected first hydrophobic material forms a pattern selected from the group consisting of: a perimeter pattern, and an annular pattern.
